(19) United States
(12) Patent Application Publication
(10) Pub. No.: US 2026/0113044 A1
(43) Pub. Date: Apr. 23, 2026

(54) Duty Cycle Error Cancellation For Phase-Locked Loops

(71) Applicant: MediaTek Inc., Hsinchu City (TW)

(72) Inventor: Khalid Ali Abu El Yazid Eissa, Cambridge (GB)

(73) Assignee: MediaTek Inc., Hsinchu City (TW)

(21) Appl. No.: 19/328,217

(22) Filed: Sep. 14, 2025

Related U.S. Application Data
(60) Provisional application No. 63/710,049, filed on Oct. 22, 2024.

(51) Int. Cl. H03L 7/099; H03K 5/131; H03K 5/14; H03L 7/085

(52) U.S. Cl. CPC H03L 7/099; H03K 5/131; H03K 5/14; H03L 7/085

(57) ABSTRACT

Various solutions for duty cycle error cancellation method and phase-locked loop (PLL) circuit are described. The PLL circuit may measure a duty cycle of a reference signal from an external oscillator by an internal clock signal to obtain a digital cycle value. The PLL circuit may shift an edge of a divided signal according to the digital cycle value to obtain a time alignment divided signal. The PLL circuit may compare the time alignment divided signal with the reference signal to generate a phase-locked signal.

### CROSS REFERENCE TO RELATED PATENT APPLICATION(S)

The present disclosure is part of a non-provisional application claiming the priority benefit of U.S. Patent Application No. 63/710,049, filed 22 Oct. 2024, the content of which herein being incorporated by reference in its entirety.

### TECHNICAL FIELD

The present disclosure is generally related to phase-locked loops and, more particularly, to duty cycle error (DCE) cancellation for phase-locked loops (PLL).

### BACKGROUND

Unless otherwise indicated herein, approaches described in this section are not prior art to the claims listed below and are not admitted as prior art by inclusion in this section.

FIG. 1 is a circuit diagram depicting a conventional Phase-Locked Loop (PLL). Referring to FIG. 1, a PLL may include a phase detector 101, a processing and loop-filter 102, an Oscillator that can be either Voltage-Controlled Oscillator (VCO) or Digitally-Controlled Oscillator and a divider 104, which is a control system that synchronizes a phase of an output signal VO with a reference signal XO. It's widely used in communication systems, frequency synthesis, and clock generation. In a PLL, noise may be introduced due to various factors, with Phase-Modulation (PM) Noise and Duty-Cycle (DC) Noise being two significant contributors. PM noise arises from fluctuations in the phase of the output signal, often caused by imperfections in the PLL's components. DC noise, on the other hand, is linked to irregularities in the duty cycle of the signal, typically resulting from power supply fluctuations or waveform distortion. Notably, DC noise can be up to 10 dB higher than PM noise, making it a more prominent source of interference in many applications.

DC noise can be mitigated through XO rise/fall averaging, which helps to smooth out the irregularities in the duty cycle. There are two primary methods to achieve this: Reference (REF) Frequency Doubling and Dual-Edge Locking. REF Frequency Doubling involves using a reference signal that operates at double the frequency, effectively reducing the impact of DC noise by averaging the transitions more evenly. On the other hand, Dual-Edge Locking utilizes both the rising and falling edges of the reference signal to lock the PLL, further enhancing the averaging process and minimizing the effects of duty-cycle related noise.

While REF Frequency Doubling can help reduce DC noise, it also introduces certain challenges. One notable issue is that the duty-cycle error (DCE) of the XO can lead to cycle-to-cycle errors in the output of the doubler going to the PLL. FIG. 2 is a diagram depicting a Frequency Doubling PLL with cycle-to-cycle error. As shown in FIG. 2, the frequency doubling circuit 201 would be triggered by the rising edge and falling edge of the reference signal XO. If the reference signal XO has the DCE, the adjacent pulses will have a different duty cycle. These errors result from inconsistencies between successive cycles of the signal, causing distortion in the waveform. As a consequence, a spectral spur can appear in the output, resulting in an unwanted frequency component in the signal spectrum 202. This spur can degrade the overall signal quality and interfere with the performance of the system, particularly in high-precision applications.

Dual-Edge Locking offers an alternative approach to mitigating DC noise, leveraging both the rising and falling edges of the reference signal to improve signal accuracy. One example of this technique is the use of a Double-Sampler and Gm (transconductance) amplifiers in the PLL loop. As shown in FIG. 3, the Double-Sampling Phase Detector (DSPD) 301 ensures better synchronization between signal edges, while the Gm amplifier 302 helps to maintain a linear response. However, a challenge arises when DCE occurs in this setup, as it can cause a conversion from DC noise into phase modulation (PM) noise. This effect leads to distortion in the signal, as the DC error is transformed into unwanted phase fluctuations. Additionally, the excessive duty-cycle error (DCE) can affect the Double-Sampling Phase Detector 301 and cause common-mode output CM at the V+ and V-terminals, which drive the Gm amplifier 302 into saturation, further degrading the system's performance by limiting its ability to accurately track the reference signal.

FIG. 4 is a circuit diagram depicting an example PLL. Referring to FIG. 4, the PLL employs a Duty-Cycle Correction (DCC) mechanism before the reference signal XO is input into the PLL, ensuring more accurate signal processing. This correction process includes Power-On Calibration (POC) 401, which compensates for variations in process and voltage (PV), providing a stable starting point for the PLL. The accuracy of this method is limited by the DCE, which can range from 40-50 picoseconds (ps). To achieve much higher accuracy, the system also features On-The-Fly (OTF) calibration 402, which dynamically corrects for temperature T variations during operation. While OTF calibration 402 offers better accuracy, it requires an additional feedback loop to continuously monitor in real-time. Both POC & OTF calibrations are in XO reference path and add significant noise to the XO reference signal.

### SUMMARY

The following summary is illustrative only and is not intended to be limiting in any way. That is, the following summary is provided to introduce concepts, highlights, benefits and advantages of the novel and non-obvious techniques described herein. Select implementations are further described below in the detailed description. Thus, the following summary is not intended to identify essential features of the claimed subject matter, nor is it intended for use in determining the scope of the claimed subject matter.

An objective of the present disclosure is to propose low-noise solutions or schemes that address the aforementioned issues related to the effect of duty cycle error on the phase-locked loops.

In one aspect, a method for cancelling an effect of duty cycle error from an external oscillator may involve a circuit measuring a duty cycle of a reference signal from the external oscillator by an internal clock signal to obtain a digital cycle value. The method may also involve the circuit shifting an edge of a divided signal according to the digital cycle value to obtain a time alignment divided signal. The method may further involve the circuit comparing the time alignment divided signal with the reference signal to generate the phase-locked signal.

In another aspect, a phase-locked loop (PLL) circuit is disclosed. The PLL circuit includes a controllable oscillator, a phase detector, a duty cycle error (DCE) measurement circuit, a divider circuit and a time alignment circuit. The controllable oscillator is configured to generate an internal clock signal. The phase detector is coupled to the controllable oscillator, comprising a first input terminal and a second input terminal. The first input terminal of the phase detector is coupled to an external oscillator to receive a reference signal. The second input terminal of the phase detector receives a time alignment divided signal. The DCE measurement circuit is configured to measure a duty cycle of the reference signal by the internal clock signal generated from the controllable oscillator to obtain a digital cycle value. The divider circuit is coupled to the controllable oscillator and is configured to generate a divided signal. The time alignment circuit is coupled to the DCE measurement circuit and the divider circuit, and is configured to shift an edge of the divided signal according to the digital cycle value to obtain a time alignment divided signal. The phase detector is configured to compare the time alignment divided signal with the reference signal to control the controllable oscillator to generate the phase-locked signal.

It is noteworthy that, although description provided herein may be in the context of certain DCE sampling divider and edge adjusting technologies for PLL, the proposed concepts, schemes, and any variation(s)/derivative(s) thereof may be implemented in, for, and by other types of PLL technologies and topologies such as, for example and without limitation, REF-Doubling PLLs, Dual-Edge Locking PLLs, PFD-CP PLLs, Sampler-Gm PLLs, All-Digital PLLs (ADPLLs), and may be applied to both Integ-N and Frac-N PLLs. Thus, the scope of the present disclosure is not limited to the examples described herein.

### BRIEF DESCRIPTION OF THE DRAWINGS

The accompanying drawings are included to provide a further understanding of the disclosure and are incorporated in and constitute a part of the present disclosure. The drawings illustrate implementations of the disclosure and, together with the description, serve to explain the principles of the disclosure. It is appreciable that the drawings are not necessarily in scale as some components may be shown to be out of proportion than the size in actual implementation in order to clearly illustrate the concept of the present disclosure.

FIG. 1 is a circuit diagram depicting a conventional Phase-Locked Loop (PLL).

FIG. 2 is a diagram depicting a Frequency Doubling PLL with cycle-to-cycle error.

FIG. 3 is a diagram depicting a Dual-Edge Locking PLL with DC-to-PM noise and saturation issues.

FIG. 4 is a circuit diagram depicting an example PLL employing POC and OTF calibration.

FIG. 5 illustrates an example of implementation of a phase-locked loop in accordance with the present disclosure.

FIG. 6 illustrates an example of implementation of the DCE measurement circuit of the phase-locked loop in accordance with the present disclosure.

FIG. 7A to FIG. 7C illustrate waveform diagrams depicting DCE measurement issues in accordance with the present disclosure when the phase error between internal clock signal ICK and reference signal XO is very small.

FIG. 8 illustrates a waveform diagram depicting the operation of the digital delay line circuit DDL and the counter circuit CTR in accordance with the present disclosure.

FIG. 9 illustrates a flowchart depicting the operation of the digital control circuit DCTRL in accordance with the present disclosure.

FIG. 10 illustrates a waveform diagram depicting an operation of the time alignment circuit 606 in accordance with the present disclosure.

FIG. 11 illustrates an example of a circuit block diagram of the time alignment circuit 606 in accordance with the present disclosure.

FIG. 12 illustrates a waveform diagram depicting an operation of the circuits shown in FIG. 13 in accordance with the present disclosure.

FIG. 13 illustrates a circuit diagram depicting the counter delay circuit 1302 in accordance with the present disclosure.

FIG. 14 illustrates a waveform diagram depicting different time alignment results in different enable signals in accordance with the present disclosure.

FIG. 15 illustrates a flowchart depicting an operation of the digital control circuit DCTRL in accordance with the present disclosure.

FIG. 16 illustrates an example of implementation of a phase-locked loop in accordance with the present disclosure.

FIG. 17 illustrates an example of a circuit block diagram of the time alignment circuit in accordance with the present disclosure.

FIG. 18 illustrates a waveform diagram depicting an operation of the circuits in FIG. 19 in accordance with the present disclosure.

FIG. 19 illustrates a circuit diagram depicting the rising delay circuit in accordance with the present disclosure.

FIG. 20 illustrates a flowchart depicting an operation of the digital control circuit DCTRL in accordance with the present disclosure.

FIG. 21 illustrates a flowchart depicting a method for canceling the effect of duty cycle error in accordance with the present disclosure.

FIG. 22 illustrates a flowchart depicting the sub-step of the step S2302 of the method for canceling the effect of duty cycle error in accordance with the present disclosure.

FIG. 23 illustrates a flowchart depicting the sub-step of the step S2303 of the method for canceling the effect of duty cycle error in accordance with the present disclosure.

FIG. 24 illustrates a flowchart depicting the sub-step of the step S2303 of the method for canceling the effect of duty cycle error in accordance with the present disclosure.

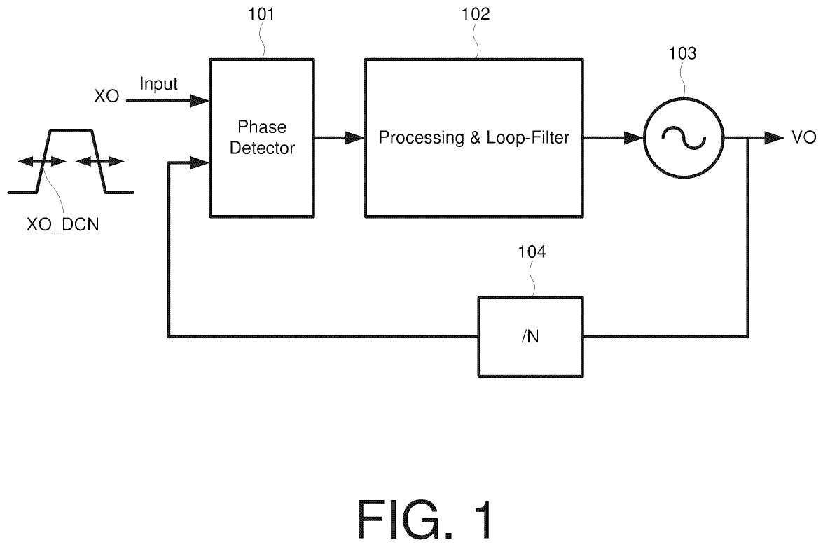

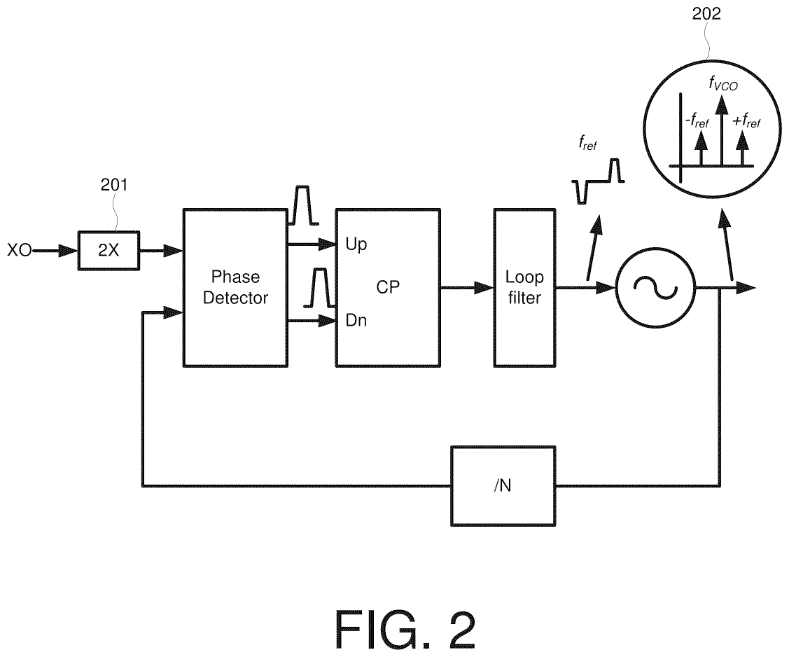

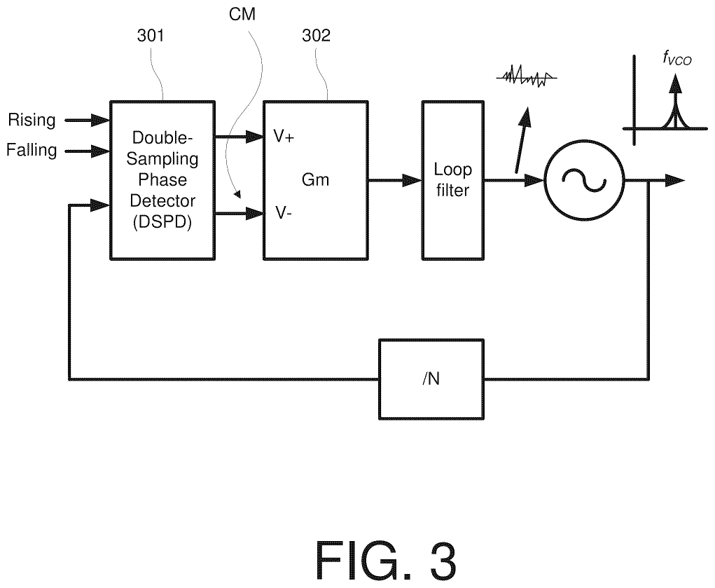

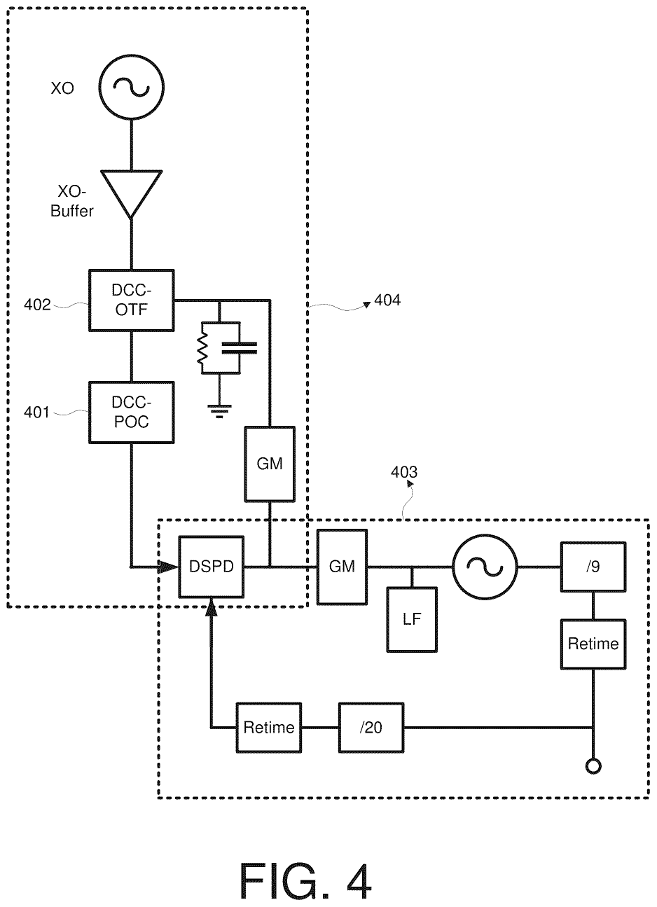

### DETAILED DESCRIPTION OF PREFERRED IMPLEMENTATIONS

Detailed embodiments and implementations of the claimed subject matters are disclosed herein. However, it shall be understood that the disclosed embodiments and implementations are merely illustrative of the claimed subject matters which may be embodied in various forms. The present disclosure may, however, be embodied in many different forms and should not be construed as limited to the exemplary embodiments and implementations set forth herein. Rather, these exemplary embodiments and implementations are provided so that description of the present disclosure is thorough and complete and will fully convey the scope of the present disclosure to those skilled in the art. In the description below, details of well-known features and techniques may be omitted to avoid unnecessarily obscuring the presented embodiments and implementations.

### Overview

Implementations in accordance with the present disclosure relate to various techniques, methods, schemes and/or solutions pertaining to Duty Cycle Error Cancellation in Phase Locked Loops. According to the present disclosure, a number of possible solutions may be implemented separately or jointly. That is, although these possible solutions may be described below separately, two or more of these possible solutions may be implemented in one combination or another.

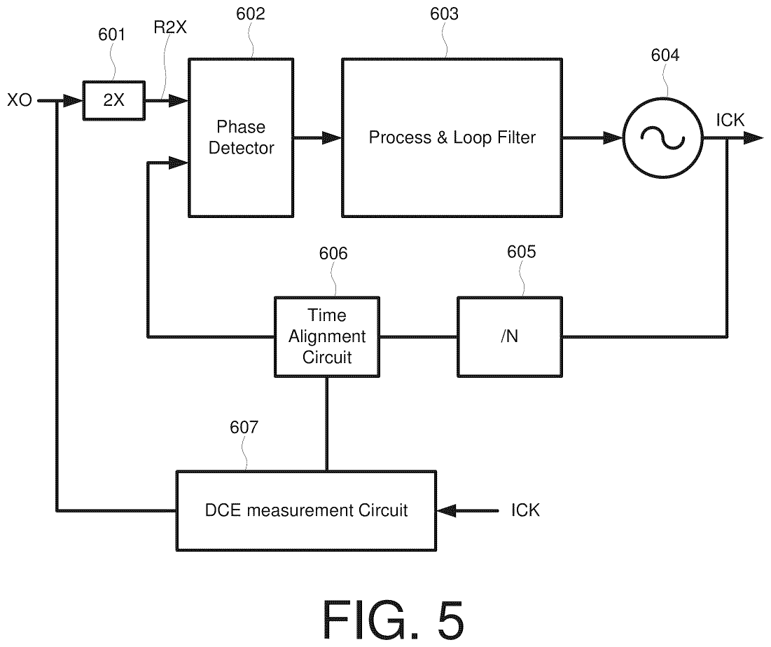

FIG. 5 illustrates an example of implementation of a phase-locked loop in accordance with the present disclosure. Referring to FIG. 5, the phase-locked loop is implemented based on the frequency doubling PLL topology in accordance with the present disclosure. The phase-locked loop includes a frequency doubling circuit 601, a phase detector 602, a process and loop filter 603, a controllable oscillator 604, a frequency divider circuit 605, a time alignment circuit 606 and a duty cycle error (DCE) measurement circuit 607.

In the original frequency doubling PLL, the phase detector 602 receives the double frequency reference signal R2X and the divided signal DV from the frequency divider circuit 605, and outputs a frequency difference signal to the process and loop filter 603. The process and loop filter 603 outputs a control signal to the controllable oscillator 604 according to the frequency difference signal. And the controllable oscillator 604 outputs an internal clock signal ICK and adjusts the frequency of the internal clock signal ICK according to the control signal.

In the present disclosure, the time alignment circuit 606 and the DCE measurement circuit 606 are implemented. The reference signal XO from the external crystal oscillator is output to the frequency doubling circuit 601 and the DCE measurement circuit 607. The DCE measurement circuit 607 is used for measuring the duty cycle of the reference signal XO by the internal clock signal ICK, whose frequency is higher than the frequency of the reference signal XO, such that a digital cycle value of the duty cycle is obtained. Afterward, the time alignment circuit 606 can adjust the shifting of an edge of the divided signal according to the digital cycle value to obtain a time alignment divided signal such that the rising edges of the double frequency reference signal R2X and the rising edges of time alignment divided signal can be aligned.

In some implementations, the process and loop filter 603 may be implemented by a loop filter and a charge pump, and the controllable oscillator 604 may be implemented by a voltage-controlled oscillator when the design of the PLL adopts a standard PLL topology. In some implementations, when the design of the PLL adopts an All-digital PLL topology, the phase detector 602 may be implemented by a digital phase detector, which may involve look-up table or digital logic circuit, the process and loop filter 603 may be implemented by a digital filter, which may involve a Finite Impulse Response (FIR) or an Infinite Impulse Response (IIR), and the controllable oscillator 604 may be implemented by a digital controlled oscillator, which may involve a digital delay line, a ring oscillator and a look-up table.

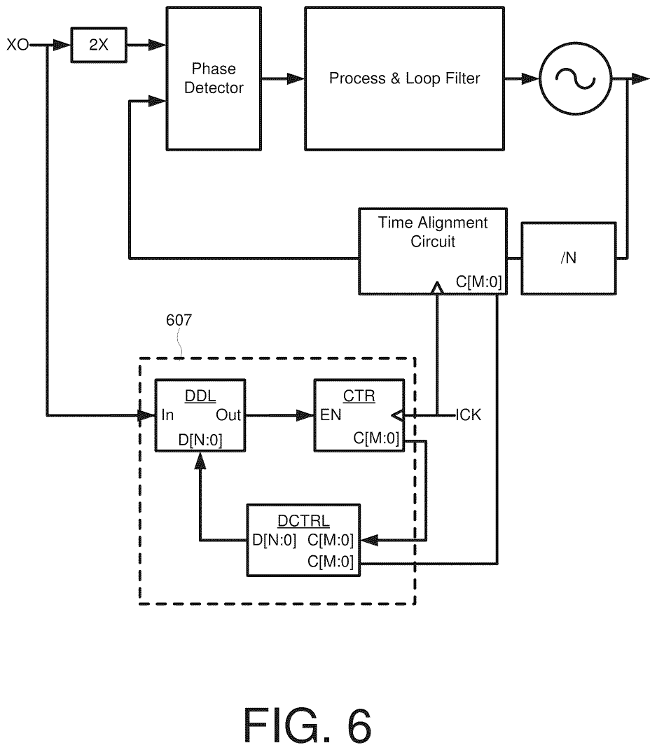

FIG. 6 illustrates an example of implementation of the DCE measurement circuit 607 of the phase-locked loop in accordance with the present disclosure. Referring to FIG. 6, the DCE measurement circuit 607 includes a digital delay line circuit DDL, a counter circuit CTR and a digital control circuit DCTRL.

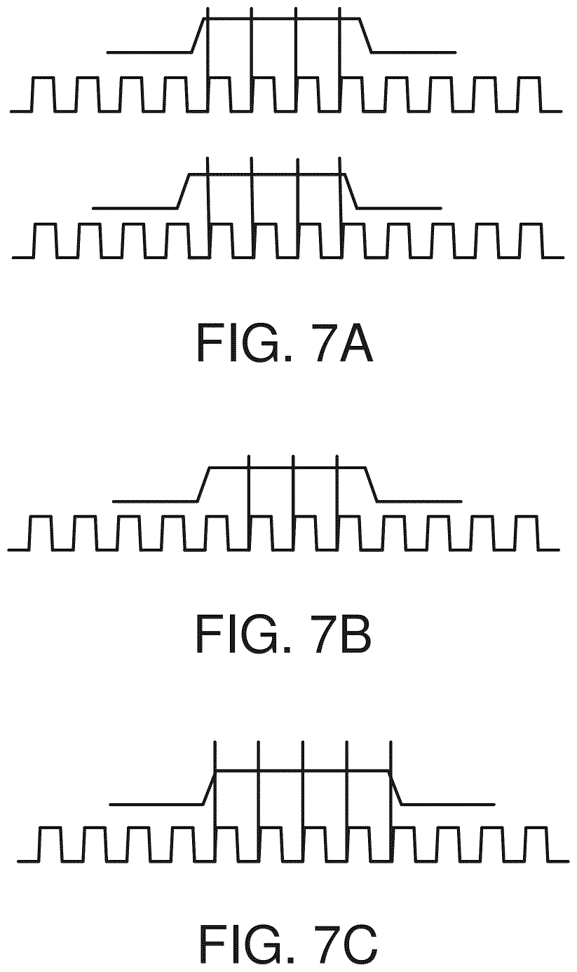

FIG. 7A to FIG. 7C illustrate waveform diagrams depicting DCE measurement issues in accordance with the present disclosure when the phase error between internal clock signal ICK and reference signal XO is very small. Referring to FIG. 7A to FIG. 7C, this is just a drawing example for illustration, with ICK frequency being x4 times XO frequency, the frequency of ICK in general is not limited to only 4 times the frequency of XO and can actually be any arbitrary frequency. It is also assumed that the reference signal XO is directly input to the counter circuit CTR in this example. In a normal situation, as shown in FIG. 7A, the counter circuit CTR would count to 4 after 4 rising edges of the internal clock signal ICK, which means the duty cycle of the reference signal XO is sampled at 4 rising edges. However, if the phase of the internal clock signal ICK is misaligned, as shown in FIG. 7B, the counter circuit CTR would count to 3 after 3 rising edges of the internal clock signal ICK. Similarly, in FIG. 7C, the counter circuit CTR would count to 5 after 5 rising edges of the internal clock signal ICK. This misalignment would cause a significant error.

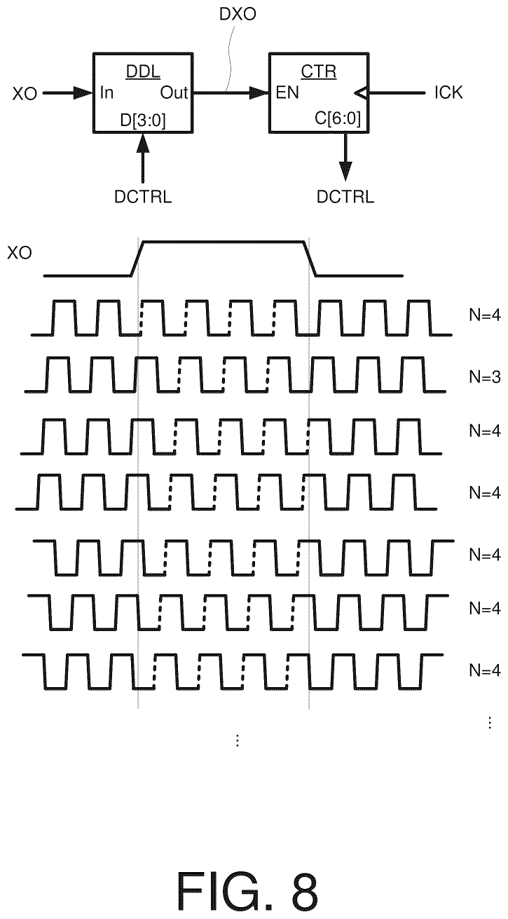

FIG. 8 illustrates a waveform diagram depicting the operation of the digital delay line circuit DDL and the counter circuit CTR in accordance with the present disclosure. Referring to FIG. 8, the previous error was pure because of the relative phase between the internal clock signal ICK and the reference signal XO. In this example, the reference signal XO has been sequentially delayed 7 times according to the delaying value D [3:0] output from the digital control circuit DCTRL by the digital delay line circuit DDL. And the counter circuit CTR measures the duty cycle of the delayed reference signal XOD according to the rising edge of the internal clock signal ICK by counting the rising edges on logic 1 state of the delayed reference signal XOD. The delay reference signal XOD serves as the enabled signal of the counter circuit CTR. When the delay reference signal XOD is in logic 1 state, the counter circuit CTR is enabled and starts counting. Each time the counter circuit CTR finishes the counting, the delay counting value N (C[6:0]) is output to the digital control circuit DCTRL. The digital control circuit DCTRL averages the delay counting values N (C[6:0]) output from the counter circuit CTR, and then rounds the average value to the nearest integer to serve as the digital cycle value. In this example, the digital cycle value is 4.

In the above embodiment, due to the operation mechanism of the digital delay line circuit DDL, the counter circuit CTR and the digital control circuit DCTRL, the measurement error originally caused by the relative phase between the internal clock signal ICK and the reference signal XO can be calibrated. In this example, the calibration resolution can be represented as ±(½T_{VCO}+T_{VCO}/2^{D}^{ₙ}=±2^{D}^{ₙ}⁻¹+½^{D}^{ₙ}T_{BCO}≈±½T_{VCO}, where Dₙ represents the number of the input bits of the delaying value D [3:0] of the digital delay line circuit DDL.

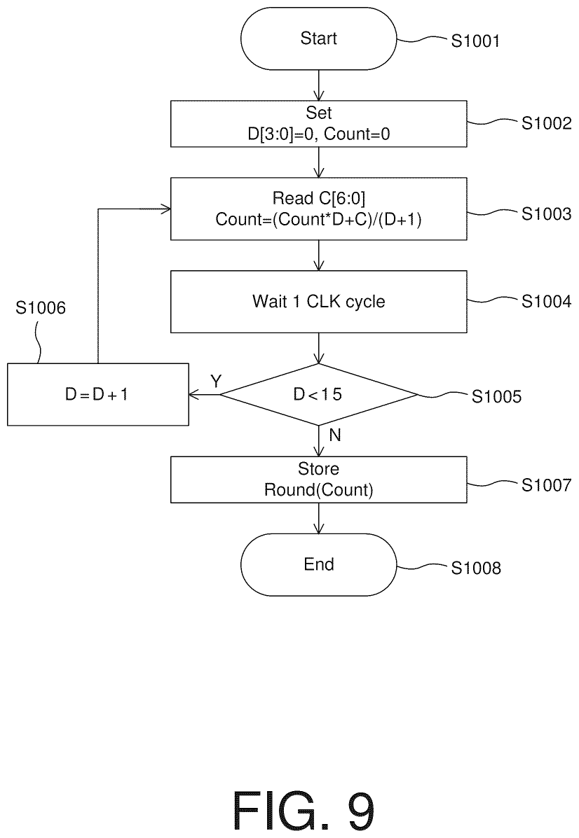

FIG. 9 illustrates a flowchart depicting the operation of the digital control circuit DCTRL in accordance with the present disclosure. Referring to FIG. 9, the operation includes the steps as follows.

In step S1001, the operation starts.

In step S1002, variable D [3:0] and variable Count are set to zero by the digital control circuit DCTRL. As the following implementation, the variable D [3:0] may be the delaying value output to the digital delay line circuit DDL.

In step S1003, the digital control circuit DCTRL reads the delay counting value C[6:0] from the counter circuit CTR and calculates the variation Count by Count=(Count*D+C)/(D+1), where C may be referred to as the delay counting value C[6:0].

In step S1004, the operation waits for 1 clock cycle.

In step S1005, it is determined whether the variable D [3:0] is smaller than 15 or not. If the variable D [3:0] is smaller than 15, the step S1006 is performed. If the variable D [3:0] is greater than 15, the step S1007 is performed.

In step S1006, the variable D [3:0] is incremented by 1. And then the step S1003 is returned. Please refer to FIG. 9, in the initial state, D [3:0] and Count are 0. The digital control circuit DCTRL reads the delay counting value C[6:0] for the first time, which is 4. The variable Count is (0*0+4)/(0+1)=4. When the variable D [3:0] is 1 by step S1006, the digital control circuit DCTRL reads the delay counting value C[6:0] for the second time, which is 3. The variable Count is (4*1+3)/(1+1)=3.5. When the variable D [3:0] is 2 by step S1006, the digital control circuit DCTRL reads the delay counting value C[6:0] for the third time, which is 4. The variable Count is (3.5*2+4)/(2+1)=3.66666. When the variable D [3:0] is 4 by step S1006, the digital control circuit DCTRL reads the delay counting value C[6:0] for the fourth time, which is 4. The variable Count is (3.66666*3+4)/(3+1)−3.75. Therefore, the steps S1003 to S1006 substantially perform average of the delay counting value C[6:0] by the recursion method.

In step S1007, the rounded value of Count Round (Count) is stored. The digital control circuit DCTRL rounds the variable Count to the nearest integer. In this example, the integer is 4.

In step S1008, the operation ends.

In the above implementation, the DCE measurement circuit 607 performs the DCE measurement during the power-on sequence. That is, when the power is turned on, through the operation of the digital delay line circuit DDL, the counter circuit CTR, and the digital control circuit DCTRL, the average delay counting values N (C[6:0]) are first calculated. Afterward, the digital control circuit DCTRL outputs the digital cycle value, that is, the average delay counting values N (C[6:0]), to the time alignment circuit 606, to adjust the delay of an edge of the divided signal DV. This eliminates the effect of the cycle-to-cycle error from the double frequency reference signal R2X.

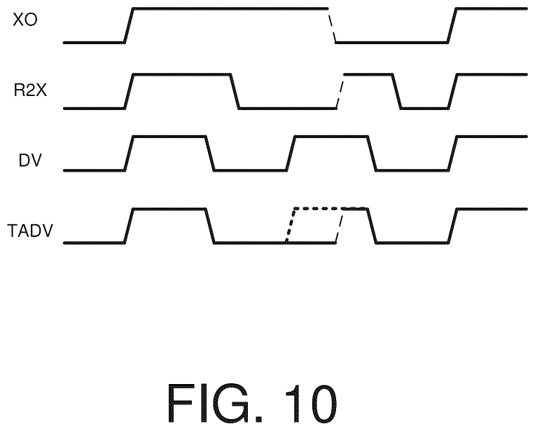

FIG. 10 illustrates a waveform diagram depicting an operation of the time alignment circuit 606 in accordance with the present disclosure. Referring to FIG. 10, the duty cycle of the reference signal XO in this example exceeds 50%; therefore, the double frequency reference signal R2X includes a cycle-to-cycle error. People having ordinary skill in the art can observe that the time between the rising edge of the first pulse of the double frequency reference signal R2X and the rising edge of the second pulse of the double frequency reference signal R2X is greater than the time between the rising edge of the second pulse of the double frequency reference signal R2X and the rising edge of the third pulse of the double frequency reference signal R2X. However, the time intervals between the rising edges of each pulse in the divided signal DV from the frequency divider circuit 605 are the same. Therefore, in this example, the rising edge of the second pulse of the divided signal DV is shifted. The time alignment circuit 606 adjusts the delay of the second rising edge of the divided signal DV by the digital cycle value (C[6:0]) to obtain a time alignment divided signal TADV, such that the second rising edge of the time alignment divided signal TADV is aligned with the second rising edge of the double frequency reference signal R2X.

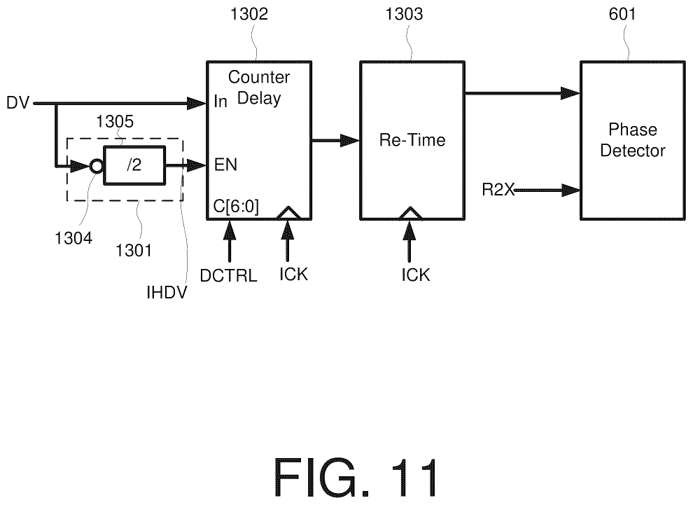

FIG. 11 illustrates an example of a circuit block diagram of the time alignment circuit 606 in accordance with the present disclosure. Referring to FIG. 11, the time alignment circuit 606 includes an enable signal generating circuit 1301 and a counter delay circuit 1302. Furthermore, in this implementation, a re-timing circuit 1303 is also provided between the phase detector 601 and the counter delay circuit 1302. The re-timing circuit 1303 is used to block the noise from the frequency divider circuit 605 and time alignment circuit 606, ensuring that no additional noise is introduced into the phase detector 601.

In this implementation, the enable signal generating circuit 1301 is implemented using an inverter 1304 and a divide-by-2 divider circuit 1305. Referring to FIG. 10, the divided signal DV is inverted and divided by 2 to ensure that the enable signal EN can be activated on one pulse period and deactivated on the next pulse period, because only the edge of the 2N-th pulse of the divided signal DV needs to be delayed to align with the double frequency reference signal R2X in this example. The input terminal of the counter delay circuit 1302 receives the divided signal DV. The enable terminal of the counter delay circuit 1302 receives the enable signal EN. The clock terminal of the counter delay circuit 1302 receives the internal clock signal ICK. The digital port of the counter delay circuit 1302 receives the digital cycle value C[6:0] from the digital control circuit DCTRL. The output terminal of the counter delay circuit 1302 outputs the time alignment divided signal TADV.

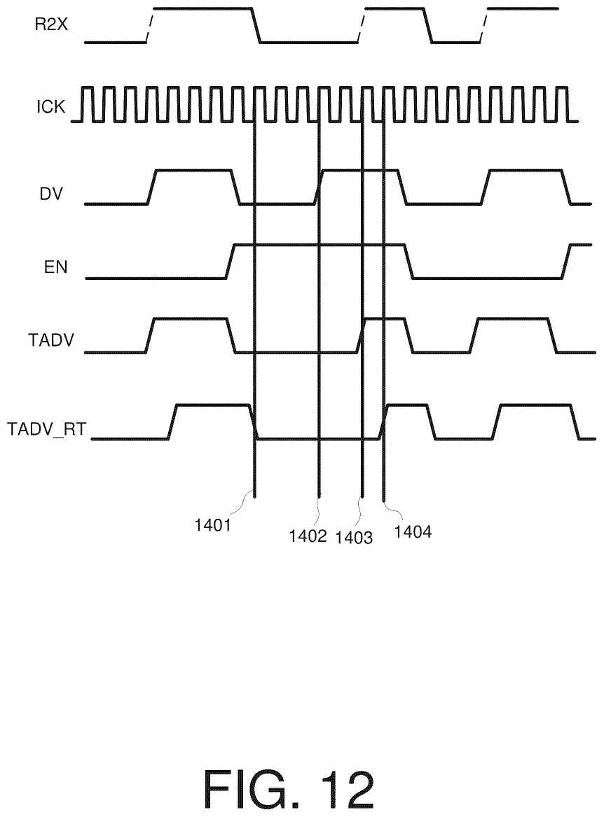

FIG. 12 illustrates a waveform diagram depicting an operation of the circuits shown in FIG. 11 in accordance with the present disclosure. Referring to FIG. 12, in this case, the digital cycle value C[6:0] is, for example, 10. When the enable signal, implemented by the inverted half-divided signal IHDV, is activated, the counter delay circuit 1302 is enabled. However, the divided signal DV switches from logic 0 to logic 1 at the time point 1402. Therefore, the counter delay circuit 1302 begins counting from the time point 1402 during each clock cycle until it reaches the digital value C[6:0] sent from the digital control circuit DCTRL. After the second rising edge of the internal clock signal ICK from the time point 1402, the time alignment divided signal TADV rises on the third rising edge 1403 of the internal clock signal ICK as the divided signal DV is logic high and the counter delay circuit 1302 counts up to the digital value C[6:0]. The re-timing circuit 1303 delays the time alignment divided signal TADV by one clock cycle of the internal clock signal ICK and outputs the delayed time alignment divided signal TADV_RT at time point 1404. It is notable that the digital cycle value obtained from the DCE measurement circuit 607 is 10, but the required digital value sent from the digital control circuit DCTRL is 2. How the digital value 2 is obtained from the digital cycle value will be explained later.

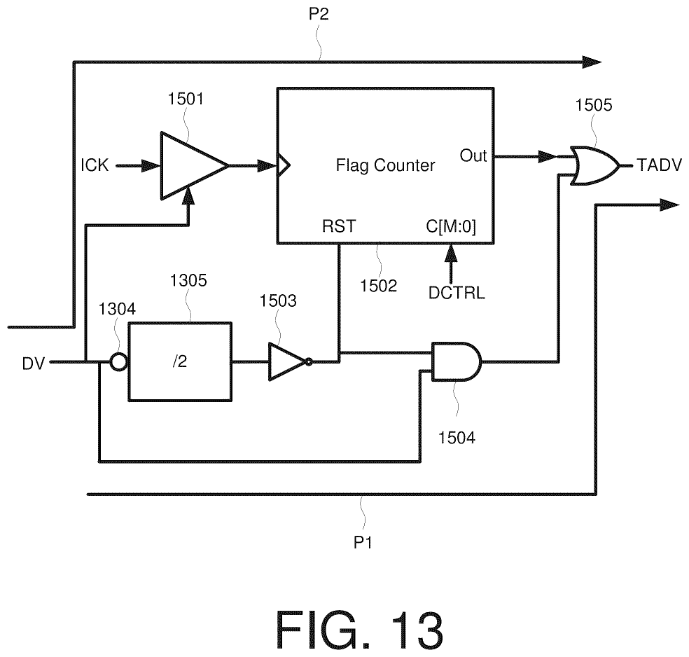

FIG. 13 illustrates a circuit diagram depicting the counter delay circuit 1302 in accordance with the present disclosure. Referring to FIG. 13, in this implementation, the counter delay circuit 1302 includes a clock enabling circuit 1501, a flag counter 1502, an inverter 1503, an AND gate 1504 and an OR gate 1505. Two paths, P1 and P2, are shown in FIG. 13. The flag counter 1502 is a counter for a target input. When the counting value of the flag counter 1502 reaches the target value, the flag is set, meaning the output terminal of the flag counter 1502 outputs a logic level of 1. In this case, the target value is the difference between the digital cycle value C[6:0] and a preset value, wherein the preset value may represent the 50% duty cycle. Referring to FIG. 12, the period length of the reference signal XO is about 16 clock cycles of the internal clock signal ICK. Therefore, the preset value in this case is 8.

The path P1 corresponds to the first pulse of the divided signal DV, during which the enable signal EN is deactivated. The clock enabling circuit 1501 is disabled, preventing the internal clock signal ICK from being input to the clock terminal of the flag counter 1502. Additionally, because the enable signal EN is deactivated, the inverter 1503 outputs logic 1. This causes the reset terminal of the flag counter 1502 to receive logic 1, which then makes the output terminal of the flag counter 1502 output logic 0. Moreover, when the divided signal is logic 1 and the enable signal EN remains deactivated, the AND gate 1504 outputs logic 1 and consequently, the OR gate 1505 also outputs logic 1.

The path P2 corresponds to the second pulse of the divided signal DV, during which the enable signal EN is activated. The clock enabling circuit 1501 is then enabled as the divided signal switches to logic 1, allowing the internal clock signal ICK to be input to the clock terminal of the flag counter 1502. Additionally, because the enable signal EN is activated, the inverter 1503 outputs logic 0. The reset terminal of the flag counter 1502 receives this logic 0, causing the flag counter 1502 to begin counting according to the internal clock signal ICK. Moreover, with the enable signal EN still activated, the inverter 1503 continues to output logic 0, which causes the AND gate 1504 to output logic 0. The OR gate 1505 also outputs logic 0. As a result, the time alignment divided signal TADV remains at logic 0 until the counting value of the flag counter 1502 reaches the target value, which is 10-8, at which point the time alignment divided signal TADV switches from logic 0 to logic 1.

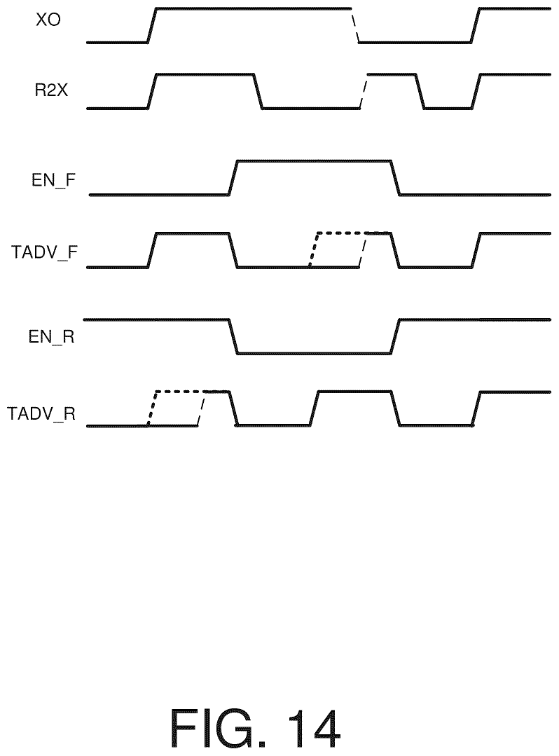

In the above implementation, the cycle-to-cycle error is correctly canceled by the time alignment divided signal TADV. However, there are two conditions that would cause different results. FIG. 14 illustrates a waveform diagram depicting different time alignment results for different enable signals in accordance with the present disclosure. Referring to FIG. 14, when the enable signal EN_F is synchronized with the falling edge of the reference signal XO, the cycle-to-cycle error is correctly canceled by the time alignment divided signal TADV_F. However, when the enable signal EN_R is synchronized with the rising edge of the reference signal XO, the incorrect time alignment divided signal TADV_R is generated, which causes a double effect of the cycle-to-cycle error.

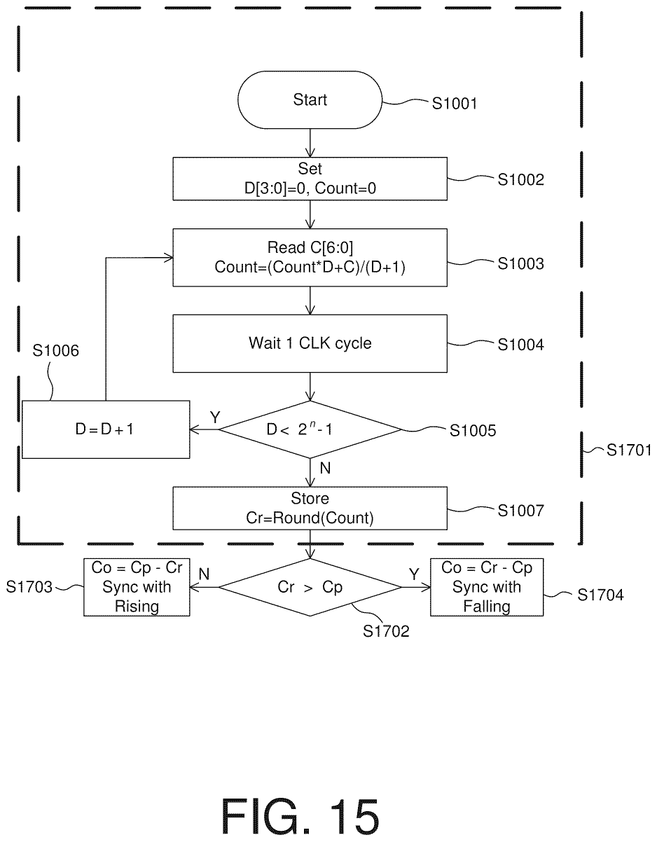

In order to avoid the incorrect condition in FIG. 14, FIG. 15 illustrates a flowchart depicting an operation of the digital control circuit DCTRL in accordance with the present disclosure. Referring to FIG. 15, the operation includes the steps as follows.

In step S1701, the step is substantially the same as the S1001 to S1007 in FIG. 9 such that the digital cycle value C[6:0] can be obtained.

In step S1702, it is determined whether the digital cycle value Cr is greater than the preset cycle value Cp. In this case, the preset cycle value Cp may be 50%, which can be represented as

$$\frac{1}{2} \frac{{T}_{ref}}{{T}_{osc}} ,$$

where T_{ref} may refer to the period of the reference signal XO, and the T_{osc} may refer to the period of the internal clock signal ICK in this implementation. When the duty cycle is smaller than 50%, the step S1703 is performed. When the duty cycle is greater than 50%, the step S1704 is performed.

In step S1703, the digital control circuit DCTRL outputs the difference value Co, which is Cp−Cr, and the enable signal EN is synchronized with the rising edge of the reference signal XO.

In step S1704, the digital control circuit DCTRL outputs the difference value Co, which is Cr−Cp, the enable signal EN is synchronized with the falling edge of the reference signal XO.

In steps S1703 and S1704, the design of the enable signal EN can adopt, for example, generating a half-divided signal and an inverted half-divided signal, and selecting one of these signals to serve as the enable signal EN based on the conditions described above.

In the above implementation, the operation method for duty cycle error cancellation implemented in a frequency doubling PLL topology and its preferred circuit implementation are introduced. In the following sections, the operation method and circuit for duty cycle error cancellation implemented in a Dual-Edge-Locking PLL topology will be explained.

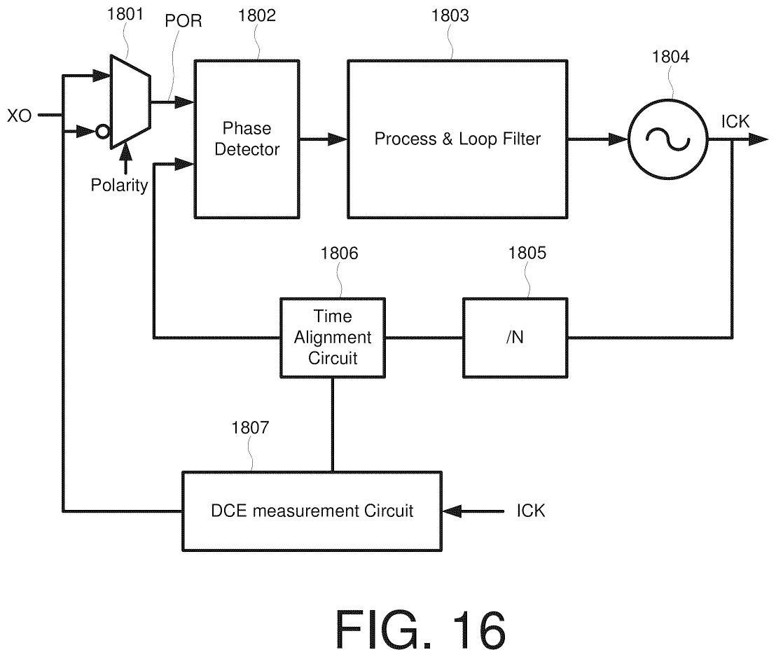

FIG. 16 illustrates an example of implementation of a phase-locked loop in accordance with the present disclosure. Referring to FIG. 16, the phase-locked loop is implemented based on the Dual-Edge-Locking PLL topology in accordance with the present disclosure. The phase-locked loop includes a phase selection circuit 1801, a phase detector 1802, a process and loop filter 1803, a controllable oscillator 1804, a frequency divider circuit 1805, a time alignment circuit 1806 and a DCE measurement circuit 1807. In this Dual-Edge-Locking PLL, the phase detector 1802 receives both the rising edge and falling edge of the output signal POR from the phase selection circuit 1801. The general operation of the PLL has been described in the above sections. Thus, the description is omitted. Furthermore, the operation of the DCE measurement circuit 1807 is also described in the above sections. Thus, the detail of the DCE measurement circuit 1807 is omitted.

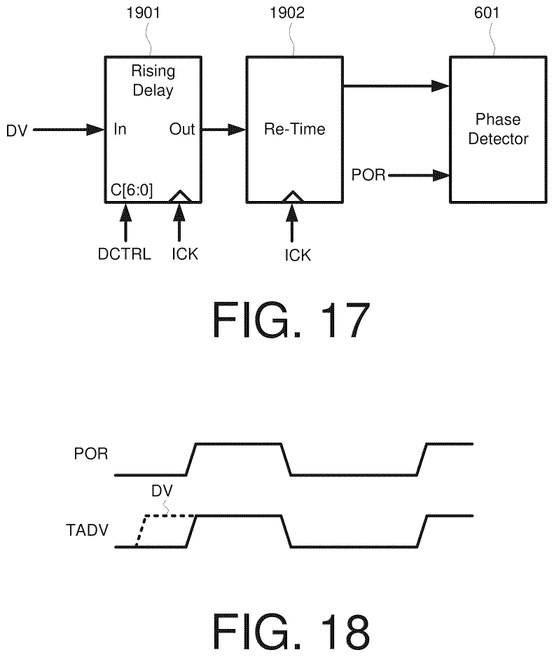

FIG. 17 illustrates an example of a circuit block diagram of the time alignment circuit 606 in accordance with the present disclosure. Referring to FIG. 17, the time alignment circuit 606 includes a rising delay circuit 1901. The rising delay circuit 1901 includes an input terminal, a clock input terminal, a digit input port and an output terminal. Additionally, in this implementation, a re-timing circuit 1902 is also provided between the phase detector 601 and the rising delay circuit 1901. Similarly, the re-timing circuit 1902 is used to block noise from the frequency divider circuit 605, ensuring that no additional noise is introduced into the phase detector 601.

FIG. 18 illustrates a waveform diagram depicting an operation of the circuits in FIG. 17 in accordance with the present disclosure. Referring to FIG. 18, in this case, the output signal POR from the phase selection circuit 1801 has a duty cycle lower than 50%. In order to eliminate the duty cycle error of the output signal POR from the phase selection circuit 1801, the rising edge of the divided signal DV should be delayed. Because the rising delay circuit 1901 in this implementation may only be used to delay the rising edge of the divided signal DV to obtain the time alignment divided signal TADV, the polarity signal Pol should be used to select either the reference signal or the inverted reference signal, depending on which has a duty cycle smaller than 50%.

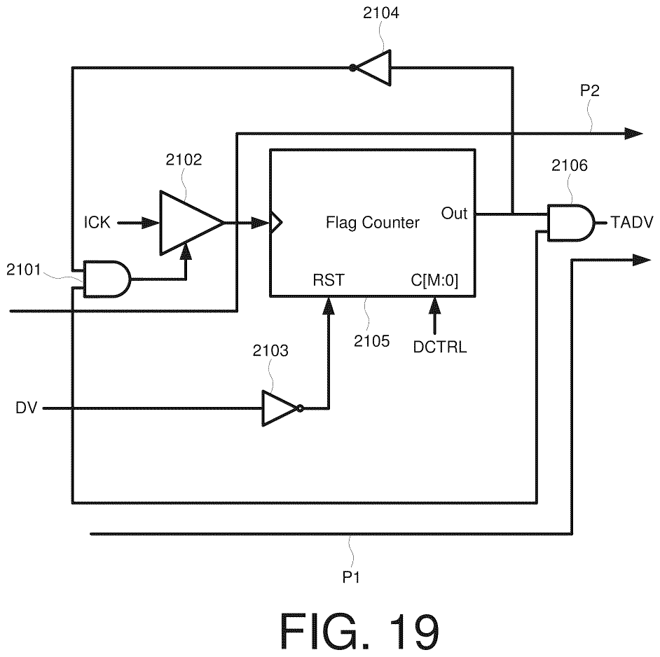

FIG. 19 illustrates a circuit diagram depicting the rising delay circuit 1901 in accordance with the present disclosure. Referring to FIG. 19, the rising delay circuit 1901 includes a first AND gate 2101, a clock enabling circuit 2102, a first inverter 2103, a second inverter 2104, a flag counter 2105, and a second AND gate 2106. Similarly, two paths, P1 and P2, are also shown in FIG. 19. The path P1 corresponds to the signal path of the falling edge of the divided signal, during which the divided signal DV is logic 0. Then, the first inverter 2103 outputs logic 1, the flag counter 2105 is reset, resulting in an output logic 0. And consequently, the second AND gate 2106 outputs logic 0.

The path P2 corresponds to the signal path of the rising edge of the divided signal, during which the divided signal DV is logic 1. The first inverter 2103 outputs logic 0 since the divided signal is logic 1. The flag counter 2105 is activated because the reset terminal of the flag counter is at logic 0. However, the output terminal of the flag counter 2105 still outputs logic 0 because the counting value of the flag counter has not yet reached the target value received from the digital control circuit DCTRL. The input terminal of the second inverter 2104 is coupled to the output terminal of the flag counter 2105, so the second inverter 2104 outputs logic 1. As a result, the first AND gate 2101 receives logic 1 from the divided signal and logic 1 from the second inverter 2104, and the first AND gate outputs logic 1. The enable terminal of the clock enabling circuit 2102 is coupled to the output terminal of the first AND gate 2101, enabling the clock enabling circuit 2102 and transmitting the internal clock to the clock terminal of the flag counter 2105. When the flag counter 2105 reaches the target value, the output terminal of the flag counter 2105 outputs logic 1. The second AND gate 2106 receives logic 1 from the divided signal DV and logic 1 from the output terminal of the flag counter 2105, and the second AND gate 2106 outputs logic 1. Therefore, the time alignment divided signal TADV is generated from the output terminal of the second AND gate 2106.

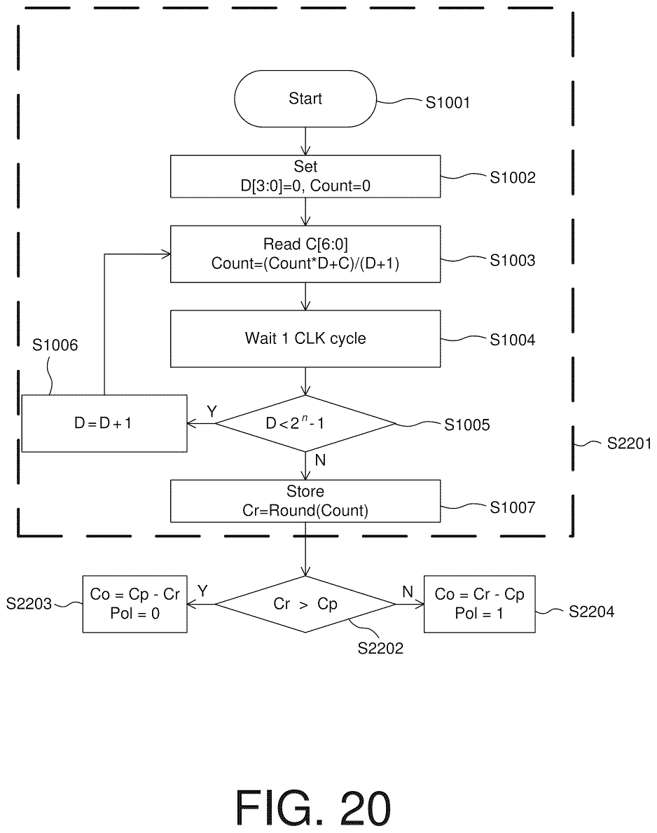

FIG. 20 illustrates a flowchart depicting an operation of the digital control circuit DCTRL in accordance with the present disclosure. Referring to FIG. 20, the operation includes the steps as follows.

In step S2201, the step is substantially the same as the S1001 to S1007 in FIG. 9 such that the digital cycle value C[6:0] can be obtained.

In step S2202, the digital cycle value Cr is greater than the preset cycle value Cp. In this case, the preset cycle value Cp may be 50%, which can be represented as

$$\frac{1}{2} \frac{{T}_{ref}}{{T}_{osc}} ,$$

where T_{ref} may refer to the period of the reference signal XO, and the T_{osc} may refer to the period of the internal clock signal ICK in this implementation. When the duty cycle is smaller than 50%, the step S2203 is performed. When the duty cycle is greater than 50%, the step S2204 is performed.

In step S2203, the digital control circuit DCTRL outputs the difference value Co, which is Cp−Cr, and the polarity signal Pol is, for example, set to logic 0 to select the reference signal XO.

In step S2204, the digital control circuit DCTRL outputs the difference value Co, which is Cr−Cp, and the polarity signal Pol is, for example, set to logic 1 to select the inverted reference signal IXO.

Although the implementation in FIG. 16 is applied to the Dual-Edge-Locking PLL topology, people having ordinary skill in the art should recognize that the implementation can also be applied to the standard PLL topology. Thus, the present invention is not limited thereto.

People having ordinary skill in the art should recognize that, between the circuits described above, additional components or circuits may be included. For example, in the circuit of FIG. 19, to achieve synchronization, a flip-flop could be coupled to both the input and output. Moreover, depending on specific requirements, other circuits tailored to meet those needs may be incorporated. As such, the present invention is not limited to the circuits explicitly described above and may encompass a broader range of possible configurations and variations.

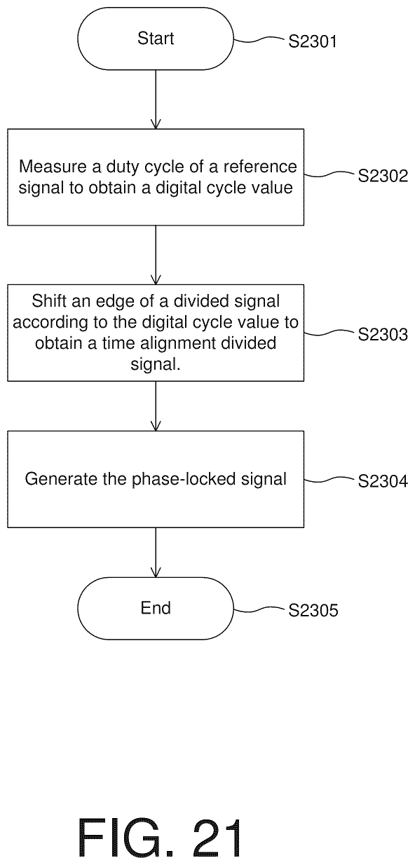

Based on the above circuit implementations, they can be summarized into a method. FIG. 21 illustrates a flowchart depicting a method for canceling the effect of duty cycle error in accordance with the present disclosure. Referring to FIG. 21, this method includes the following steps.

The method may represent an aspect of implementing various proposed designs, concepts, schemes, systems and methods described above, whether partially or entirely, including those described above. More specifically, the method may represent an aspect of the proposed concepts and schemes pertaining to generating a phase-locked signal with duty cycle cancellation and a clean reference path in a phase-locked loop. The method may include one or more operations, actions, or functions as illustrated by one or more of steps S2301, S2302, and S2303. Although illustrated as discrete steps, various steps of method may be divided into additional steps, combined into fewer steps, or eliminated, depending on the desired implementation. Moreover, the steps/sub-steps of method may be performed in the order shown in FIG. 21 or, alternatively in a different order. Furthermore, one or more of the steps/sub-steps of method may be performed iteratively. The method may be implemented by or in apparatus 606 and apparatus 607 as well as any variations thereof. The method includes the steps as follows.

In step S2301, the method starts.

In step S2302, a duty cycle of a reference signal from the external oscillator is measured by an internal clock signal to obtain a digital cycle value. The method may involve DCE measurement circuit 607, counting a counting value on the first logic state of the reference signal by internal clock signal ICK. The step may proceed from step S2302 to step S2303.

In step S2303, an edge of a divided signal is shifted according to the digital cycle value to obtain a time alignment divided signal. The method may involve a time alignment circuit 606 shifting an edge of the dividing signal.

In step S2304, the phase-locked signal is generated by comparing the time alignment divided signal with the reference signal. Since the edge of the divided signal is aligned with the reference signal or the input signal generated by the reference signal, the phase difference is cancelled when the frequency and phase of the time alignment divided signal are substantially the same as the frequency and phase of the reference signal or the input signal generated by the reference signal.

In step S2305, the method ends.

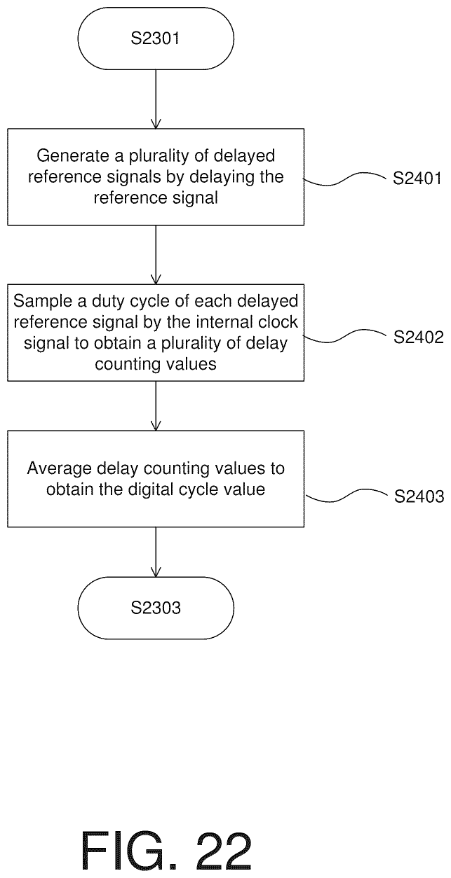

FIG. 22 illustrates a flowchart depicting the sub-step of the step S2302 of the method for canceling the effect of duty cycle error in accordance with the present disclosure. Referring to FIG. 22, the step S2302 includes the following steps.

In step S2401, a plurality of delayed reference signals is generated by delaying the reference signal. This step may involve the digital delay line DDL being input with the reference signal and the digital control circuit DCTRL inputting a delaying value to the digital delay line DDL to delay the reference signal.

In step S2402, a duty cycle of each delayed reference signal is sampled by the internal clock signal to obtain a plurality of delay counting values. The step S2402 may involve the counter circuit CTR counting the output signal of the digital delay line and calculating a rising edge of the internal clock signal to obtain a delay counting value during a first logic state of the output signal. The step S2402 may also involve the digital control circuit DCTRL determining whether the delaying value reaches a threshold, and increasing the delaying value and inputting the delaying value to the digital delay line until the delaying value reaches the threshold.

In step S2403, the plurality of delay counting values are averaged to obtain the digital cycle value. The step S2403 may involve the digital control circuit DCTRL averaging the delay counting values by, for example, the above iterative method.

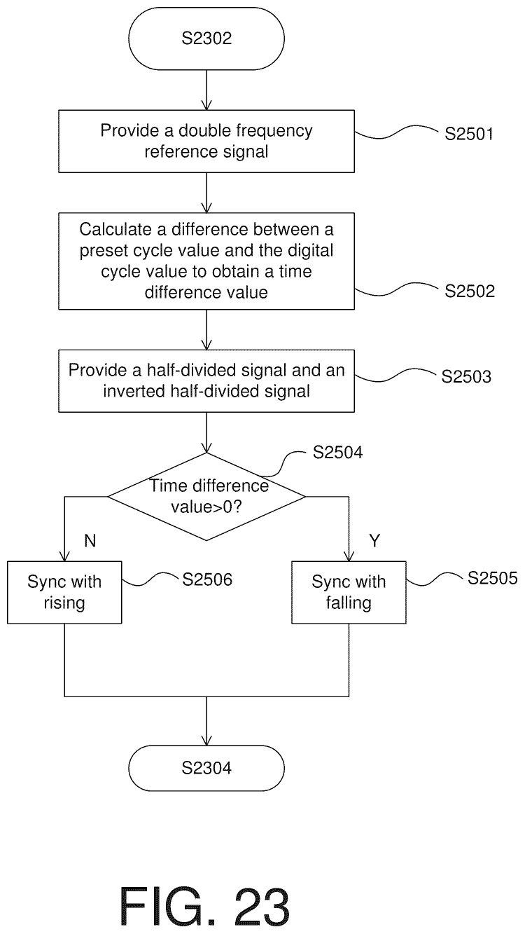

FIG. 23 illustrates a flowchart depicting the sub-step of the step S2303 of the method for canceling the effect of duty cycle error in accordance with the present disclosure. Referring to FIG. 23, in this implementation, the method adopts a double frequency reference signal R2X to be the input signal of the phase-locked loop. The step S2301 includes the following steps.

In step S2501, a double frequency reference signal is provided, wherein a rising edge of the double frequency reference signal is aligned with a rising edge of the reference signal and a falling edge of the reference signal.

In step S2502, a difference between a preset cycle value and the digital cycle value is calculated to obtain a time difference value.

In step S2503, a half-divided signal and an inverted half-divided signal are provided. The half-divided signal is generated by dividing the divided signal by 2. The inverted half-divided signal is generated by dividing the divided signal by 2 and performing an inversion.

In step S2504, it is determined whether the time difference value is positive or not. When the time difference value is positive, the step S2505 is performed. When the time difference value is negative, the step S2506 is performed.

In step S2505, one of the half-divided signal and the inverted half-divided signal is selected as an enable signal. The selected one is synchronized with the falling edge of the reference signal and counts a count value from the initial value to the time difference value from the rising edge of a pulse of the divided signal when the enable signal is activated.

In step S2506, the other one of the half-divided signal and the inverted half-divided signal is selected as an enable signal. The other one is synchronized with the rising edge of the reference signal and counts a count value from the initial value to the negative time difference value from the rising edge of a pulse of the divided signal when the enable signal is activated.

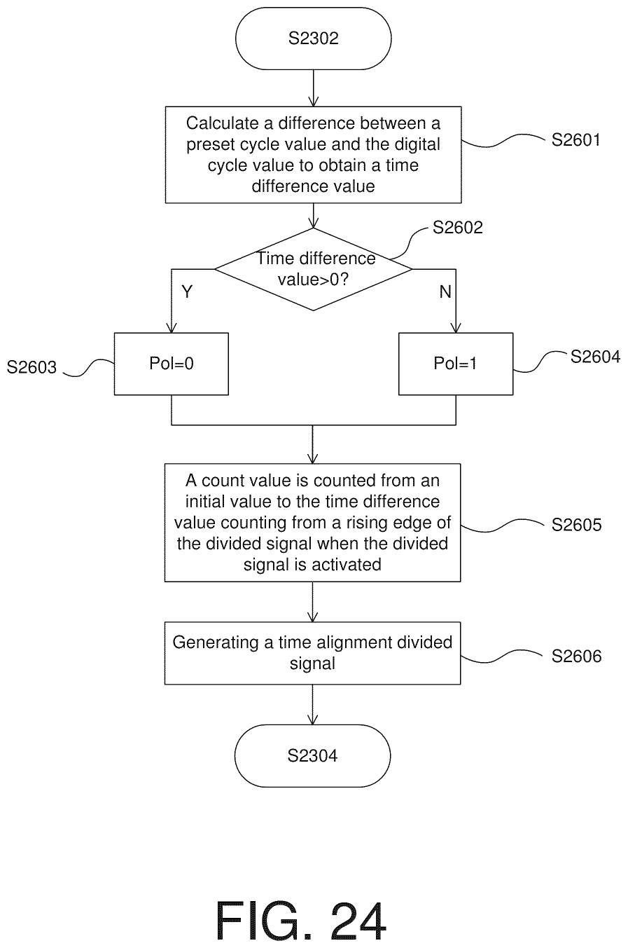

FIG. 24 illustrates a flowchart depicting the sub-step of the step S2303 of the method for canceling the effect of duty cycle error in accordance with the present disclosure. Referring to FIG. 24, in this implementation, the method adopts the reference signal XO to be the input signal of the phase-locked loop. The step S2301 includes the following steps.

In step S2601, a difference between a preset cycle value and the digital cycle value is calculated to obtain a time difference value.

In step S2602, it is determined whether the time difference value is positive or not. If the time difference value is positive, the step S2603 is performed. If the time difference value is negative, the step S2604 is performed.

In step S2603, the polarity flag Pol is set to 0, and the input signal of the PLL is the reference signal.

In step S2604, the polarity flag Pol is set to 1, and the input signal of the PLL is the inverted reference signal.

In step S2605, a count value is counted from an initial value to the time difference value, counting from a rising edge of the divided signal when the divided signal is activated.

In step S2606, a time alignment divided signal is generated. The time alignment divided signal is changed from a second logic state to the first logic state when the count value reaches the time difference value. The time alignment divided signal is changed from the first logic state to the second logic state when the divided signal changes from the first logic state to the second logic state.

In summary, the present disclosure describes a method and phase-locked loop (PLL) circuit for canceling the effect of duty cycle errors from an external oscillator. By measuring the duty cycle of the reference signal and using an internal clock signal to obtain a digital cycle value, the system shifts the edge of a divided signal to achieve time alignment. The phase detector then compares the time-aligned divided signal with the reference signal to generate a phase-locked output. This approach improves the accuracy and stability of the PLL by compensating for duty cycle errors in the reference signal. Notably, this solution can be applied to any PLL without the need for adding noisy delay-lines in the XO reference path. As a result, the REF path becomes cleaner, ensuring better signal integrity and performance.

### Additional Notes

The herein-described subject matter sometimes illustrates different components contained within, or connected with, different other components. It is to be understood that such depicted architectures are merely examples, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

Further, with respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

Moreover, it will be understood by those skilled in the art that, in general, terms used herein, and especially in the appended claims, e.g., bodies of the appended claims, are generally intended as “open” terms, e.g., the term “including” should be interpreted as “including but not limited to,” the term “having” should be interpreted as “having at least,” the term “includes” should be interpreted as “includes but is not limited to,” etc. It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to implementations containing only one such recitation, even when the same claim includes the introductory phrases “one or more” or “at least one” and indefinite articles such as “a” or “an,” e.g., “a” and/or “an” should be interpreted to mean “at least one” or “one or more;” the same holds true for the use of definite articles used to introduce claim recitations. In addition, even if a specific number of an introduced claim recitation is explicitly recited, those skilled in the art will recognize that such recitation should be interpreted to mean at least the recited number, e.g., the bare recitation of “two recitations,” without other modifiers, means at least two recitations, or two or more recitations. Furthermore, in those instances where a convention analogous to “at least one of A, B, and C, etc.” is used, in general such a construction is intended in the sense one having skill in the art would understand the convention, e.g., “a system having at least one of A, B, and C” would include but not be limited to systems that have A alone, B alone, C alone, A and B together, A and C together, B and C together, and/or A, B, and C together, etc. In those instances where a convention analogous to “at least one of A, B, or C, etc.” is used, in general such a construction is intended in the sense one having skill in the art would understand the convention, e.g., “a system having at least one of A, B, or C” would include but not be limited to systems that have A alone, B alone, C alone, A and B together, A and C together, B and C together, and/or A, B, and C together, etc. It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

From the foregoing, it will be appreciated that various implementations of the present disclosure have been described herein for purposes of illustration, and that various modifications may be made without departing from the scope and spirit of the present disclosure. Accordingly, the various implementations disclosed herein are not intended to be limiting, with the true scope and spirit being indicated by the following claims.

What is claimed is:

1. A method for cancelling an effect of duty cycle error from an external oscillator, comprising:
measuring a duty cycle of a reference signal from the external oscillator by an internal clock signal to obtain a digital cycle value;
shifting an edge of a divided signal according to the digital cycle value to obtain a time alignment divided signal; and
comparing the time alignment divided signal with the reference signal to generate a phase-locked signal.

2. The method of claim 1, wherein the measuring of the duty cycle of the reference signal from the external oscillator by the internal clock to obtain the digital cycle value further comprises:
generating a plurality of delayed reference signals by delaying the reference signal;
sampling a duty cycle of each delayed reference signal by the internal clock signal to obtain a plurality of delay counting values; and
averaging the plurality of delay counting values to obtain the digital cycle value.

3. The method of claim 2, wherein the generating of the plurality of delayed reference signals by delaying the reference signal further comprises:
inputting the reference signal to a digital delay line; and
inputting a delaying value to the digital delay line to delay the reference signal.

4. The method of claim 3, wherein the sampling of the duty cycle of each delayed reference signal by the internal clock signal to obtain a plurality of delay counting values further comprises:
sampling the output signal of the digital delay line and calculating a rising edge of the internal clock signal to obtain a delay counting value during a first logic state of the output signal;
determining whether the delaying value reaches a threshold; and
increasing the delaying value and inputting the delaying value to the digital delay line until the delaying value reaches the threshold.

5. The method of claim 1, wherein the shifting of the edge of the divided signal according to the digital cycle value to obtain the time alignment divided signal further comprises:
providing a double frequency reference signal, wherein a rising edge of the double frequency reference signal is aligned with a rising edge of the reference signal and a falling edge of the reference signal;
calculating a difference between a preset cycle value and the digital cycle value to obtain a time difference value;
providing a half-divided signal and an inverted half-divided signal, wherein the half-divided signal is generated by dividing the divided signal by 2, and wherein the inverted half-divided signal is generated by dividing the divided signal by 2 and performing an inversion;
in an event that the time difference value is positive:
selecting one of the half-divided signal and the inverted half-divided signal as an enable signal, wherein the selected one is synchronized with the rising edge of the reference signal; and
counting a count value from an initial value to the time difference value from a rising edge of a pulse of the divided signal in an event that the enable signal is activated;
in an event that the time difference value is negative:
selecting the other one of the half-divided signal and the inverted half-divided signal as an enable signal, wherein the other one is synchronized with the falling edge of the reference signal; and
counting a count value from the initial value to the time difference value from the rising edge of the pulse of the divided signal in an even that the enable signal is activated.

6. The method of claim 1, wherein the shifting of the edge of the divided signal according to the digital cycle value to obtain the time alignment divided signal further comprises:
calculating a difference between a preset cycle value and the digital cycle value to obtain a time difference value;
in an event that the divided signal is in a first logic state, counting a count value from an initial value to the time difference value from a rising edge of the divided signal; and
generating the time alignment divided signal,
wherein the time alignment divided signal is changed from a second logic state to the first logic state in an event that the count value reaches the time difference value,
wherein the time alignment divided signal is changed from the first logic state to the second logic state in an event that the divided signal is changed from the first logic state to the second logic state.

7. The method of claim 6, further comprising:
inverting the reference signal in an event that the time difference value is a negative value.

8. A phase-locked loop (PLL) circuit, comprising:
a controllable oscillator, configured to generate an internal clock signal;
a phase detector, coupled to the controllable oscillator, comprising a first input terminal and a second input terminal, wherein the first input terminal of the phase detector is coupled to an external oscillator to receive a reference signal, and the second input terminal of the phase detector is configured to receive a time alignment divided signal;
a duty cycle error (DCE) measurement circuit, configured to measure a duty cycle of the reference signal by the internal clock signal to obtain a digital cycle value;
a divider circuit, coupled to the controllable oscillator, configured to generate a divided signal; and
a time alignment circuit, coupled to the DCE measurement circuit and the divider circuit, configured to shift an edge of the divided signal according to the digital cycle value to obtain a time alignment divided signal;
wherein the phase detector is configured to compare the time alignment divided signal with the reference signal to control the controllable oscillator to generate a phase-locked signal.

9. The PLL circuit of claim 8, wherein the DCE measurement circuit comprises:
a digital delay line circuit, comprising a reference input terminal, a delaying value input terminal, and an output terminal, wherein the reference input terminal of the digital delay line circuit receives the reference signal, the output terminal of the digital delay line circuit generates a delayed reference signal according to a delaying value input from the delaying value input terminal of the digital delay line circuit;
a counter circuit, comprising an enable terminal, a clock terminal and an output port, wherein the enable terminal of the counter circuit is coupled to the output terminal of the digital delay line circuit, the clock terminal of the counter circuit receives the internal clock signal, the output port of the counter circuit outputs a delay counting value after counting the enable period by the internal clock signal; and
a digital control circuit, configured to provide the delaying value and receive the delay counting value, wherein, in an event that the digital control circuit receives the delay counting value, the digital control circuit increases the delaying value provided to the digital delay line circuit until the delaying value reaches a threshold,
wherein the digital control circuit averages a plurality of delay counting values received from the counter circuit to obtain the digital cycle value.

10. The PLL circuit of claim 8, further comprising:
a frequency doubling circuit, configured to provide a double frequency reference signal, wherein a rising edge of the double frequency reference signal is aligned with a rising edge of the reference signal and a falling edge of the reference signal.

11. The PLL circuit of claim 8, further comprising:
a re-timing circuit, coupled between the time alignment circuit and the second input terminal of the phase detector, configured to add a delay to the time alignment divided signal before being received by the phase detector.

12. The PLL circuit of claim 8, wherein the time alignment circuit comprises:
an enable signal generating circuit, configured to receive the divided signal and generate an enable signal; and
a counter delay circuit, comprising an input terminal, an output terminal, an enable terminal, a clock terminal and a digital port, wherein the input terminal of the counter delay circuit receives the divided signal, the enable terminal of the counter delay circuit receives the enable signal, the clock terminal of the counter delay circuit receives the internal clock signal, the digital port of the counter delay circuit receives the digital cycle value, the output terminal of the counter delay circuit outputs the time alignment divided signal,
wherein the counter delay circuit starts counting a count value from an initial value to the digital cycle value from the rising edge of a pulse of the divided signal and disables a next pulse of the divided signal in an event that the enable signal is in a first logic state until the count value reaches the digital cycle value, and wherein the next pulse of the divided signal is blocked until the count value reaches the digital cycle value to generate the time alignment divided signal.

13. The PLL circuit of claim 12, wherein the enable signal is an inverted half-divided signal, which is generated by dividing the divided signal by 2 and performing an inversion, in an event that a duty cycle of the reference signal is greater than 50%.

14. The PLL circuit of claim 12, wherein the enable signal is a half-divided signal, which is generated by dividing the divided signal by 2, in an event that a duty cycle of the reference signal is smaller than 50%.

15. The PLL circuit of claim 12, wherein the counter delay circuit comprises:
a clock enabling circuit, comprising an input terminal, an output terminal and an enable terminal, wherein the input terminal of the enabling circuit receives the internal clock signal, the enable terminal of the clock enabling circuit receives the divided signal, the output terminal of the clock enabling circuit is for outputting the internal clock signal when the divided signal is in the first logic state;
a flag counter, comprising a clock input terminal, a reset terminal, a digit input port and an output terminal, wherein the input terminal of the flag counter is coupled to the output terminal of the clock enabling circuit, the reset terminal of the flag counter receives the enable signal, the digit input port of the flag counter receives a time difference value, obtained from a difference between an preset cycle value and the digital cycle value, and the output terminal of the flag counter outputs a first logic state in an event that a value of an edge of a signal from the clock input terminal of the flag counter is greater than the time difference value and a signal of the reset terminal of the flag counter is in a set state;
an AND gate, comprising a first input terminal, a second input terminal and an output terminal, wherein the first input terminal of the AND gate receives the enable signal, and the second input terminal of the AND gate receives the divided signal; and
an OR gate, comprising a first input terminal, a second input terminal and an output terminal, wherein the first input terminal of the OR gate is coupled to the output terminal of the flag counter, the second input terminal of the OR gate is coupled to the output terminal of the and gate, and the output terminal of the OR gate outputs the time alignment divided signal.

16. The PLL circuit of claim 8, further comprising:
a phase selection circuit, comprising a first input terminal, a second input terminal, a polarity input terminal and an output terminal, wherein the first input terminal of the phase selection circuit receives the reference signal, the second input terminal of the phase selection circuit receives an inverted reference signal, the polarity input terminal of the phase selection circuit receives a polarity signal, and the output terminal of the phase selection circuit is coupled to the first input terminal of the phase detector,
wherein the polarity signal controls the output terminal of the phase selection circuit to output the inverted reference signal in an event that a difference between a preset cycle value and the digital cycle value is positive,
wherein the polarity signal controls the output terminal of the phase selection circuit to output the reference signal in an event that the difference between the preset cycle value and the digital cycle value is negative.

17. The PLL circuit of claim 8, wherein the time alignment circuit comprises:
a rising delay circuit, comprising a input terminal, a clock input terminal, a digit input port and an output terminal, wherein the input terminal of the rising delay circuit receives the divided signal, the clock input terminal of the rising delay circuit receives the internal clock signal, the digit input port of the rising delay circuit receives a time difference value obtained from a difference between a preset cycle value and the digital cycle value, and the output terminal of the rising delay circuit outputs the time alignment divided signal by delaying the divided signal according to the difference.

18. The PLL circuit of claim 17, wherein the rising delay circuit comprises:
a first AND gate, comprising a first input terminal, a second input terminal and an output terminal, wherein the first input terminal of the first AND gate receives the divided signal;
a clock enabling circuit, comprising an input terminal, an output terminal and an enable terminal, wherein the input terminal of the enabling circuit receives the internal clock signal, the enable terminal of the clock enabling circuit is coupled to the output terminal of the first AND gate, the output terminal of the clock enabling circuit outputs the internal clock signal in an event that a signal of the output terminal of the first AND gate is in the first logic state;
an inverter, comprising an input terminal and an output terminal, wherein the input terminal of the inverter receives the divided signal, and the output terminal of the inverter outputs an inverted divided signal;
a flag counter, comprising a clock input terminal, a reset terminal, a digit input port and an output terminal, wherein the input terminal of the flag counter is coupled to the output terminal of the clock enabling circuit, the reset terminal of the flag counter is coupled to the output terminal of the inverter, the digit input port of the flag counter receives a time difference value, obtained from a difference between an ideal cycle value and the digital cycle value, and the output terminal of the flag counter is coupled to the second input terminal of the first AND gate and outputs a first logic state in an event that a value of an edge of a signal from the clock input terminal of the flag counter is greater than the time difference value and a signal of the reset terminal of the flag counter is in a set state; and
a second AND gate, comprising a first input terminal, a second input terminal and an output terminal, wherein the first input terminal of the second AND gate is coupled to the output terminal of the flag counter, the second input terminal of the second AND gate receives the divided signal, and the output terminal of the second AND gate outputs the time alignment divided signal.
